(19) United States
(12) Patent Application Publication
(10) Pub. No.: US 2026/0214836 A1
(43) Pub. Date: Jul. 23, 2026

(54) RELEASABLE FAN MODULE ASSEMBLY

(71) Applicant: Quanta Computer Inc., Taoyuan City (TW)

(72) Inventors: Yaw-Tzorng Tsorng, Taoyuan City (TW); Tung-Hsien Wu, Taoyuan City (TW); Wen-Jui Yu, Taoyuan City (TW); Bo-Cheng Yang, Taoyuan City (TW)

(21) Appl. No.: 19/028,938

(22) Filed: Jan. 17, 2025

(51) Int. Cl. H05K 7/20; F04D 29/60

(52) U.S. Cl. CPC H05K 7/20172; F04D 29/601; H05K 7/20727

(57) ABSTRACT

A releasable fan module assembly for a computer system is disclosed. The computer system includes a chassis having a bottom panel and side walls. A top cover is joined to the side walls to cover the chassis. A releasable fan module is located on the bottom panel in proximity to one edge of the top cover. The releasable fan module includes a handle that may be positioned between a retracted position and an extended position to allow a user to remove the releasable fan module from the chassis. The assembly includes a latch mechanism on the edge of the top cover. The latch mechanism engages the handle to keep the handle in the retracted position.

### TECHNICAL FIELD

The present invention relates generally to fan modules, and more specifically, to a releasable fan module assembly that does not require opening a cover of a server to access the fan module and that blocks reverse air flow when the fan module is removed.

### BACKGROUND

Servers are employed in large numbers for high demand applications, such as network based systems or data centers. The emergence of cloud computing applications has increased the demand for data centers. Data centers have numerous servers that store data and run applications accessed by remotely connected, computer device users. A typical data center has physical rack structures with attendant power and communication connections. Each rack may hold multiple application servers and storage servers. Each server generally includes hardware components such as processors, memory devices, network interface cards, power supplies, and other specialized hardware. Each of the servers generally includes a baseboard management controller that manages the operation of the server and communicates operational data to a central management station that manages the servers of the rack.

Servers generate an enormous amount of heat due to the operation of internal electronic components such as controllers, processors, and memory. Overheating from the inefficient removal of such heat has the potential to shut down or impede the operation of such devices. Servers often include various heat sinks that are attached to the electronic components, such as processing units. Heat sinks are typically composed of thermally conductive material. Heat sinks absorb the heat from the electronic components, thus transferring the heat away from the components. The heat from heat sinks must be vented away from the server. Thus, servers are designed to rely on airflow through the interior of the device to carry away heat generated from electronic components and the heat sinks. Airflow to vent away such heat is often generated by a fan system. Thus, airflow can pass through hot electric components in the server without any reverse airflow because the internal layout of the server effectively channels the airflow in one direction.

A typical fan system for a server will include multiple fan modules in a fan array. Each fan module has a single fan attached to a fan motor. One technique of modulating fan power is using a pulse width modulation control signal to each fan module. Pulse width modulation turns the power supply to fan-on and fan-off at a fixed frequency. Duty-cycle adjustments may be made to control the speed of the fan. The larger the duty cycle, the faster the fan spins. A proper frequency must be selected since the fan speed will noticeably oscillate within a pulse-width modulation (PWM) cycle if the signal frequency is too slow.

FIG. 1A is a top perspective view of the prior art server 10, and FIG. 1B is a perspective view of the interior of the server 10 showing a fan wall 14. In general, server designs, such as a prior art server 10 include a chassis 12 that holds fan modules arranged in a fan wall 14. The fan wall 14 is usually located in front of electronic components, which are the main heat source of the server 10. The chassis 12 includes a bottom panel 20 (in FIG. 1B) and two side walls 22 and 24. A top cover 26 slides between the side walls 22 and 24 to enclose the chassis 12. The chassis 12 has a front end 30 and a rear end 32. Different electronic components such as power supplies, processors, memory devices, and the like are mounted on the bottom panel 20. A release latch 28 on the surface of the top cover 26 allows the top cover 26 to be unlocked. The top cover 26 may then be pulled away from the side walls 22 and 24 and thus expose the interior of the chassis 12 to access the fan modules in the fan wall 14 as shown in FIG. 2B.

The fan wall 14 is positioned between the front end 30 and the rear end 32 of the chassis 12. The fan wall 14 in this example has eight fan modules 40 arranged in two groups of four fan modules. The fan modules 40 form a straight line across the server 10 between the side walls 22 and 24. The fan modules 40 create airflow between the front end 30 and the rear end 32 of the chassis 12.

The individual fan modules 40 must be periodically replaced. However, it is desirable to keep the server 10 operational for as much time as possible. The modular nature of the fan modules 40 allows a defective fan module 42 as shown in FIG. 1B and FIG. 1C to be removed while the remaining fan modules 40 continue to operate to produce airflow and thus allow the server 10 to continue to operate.

However, when a fan module inside the server 10 is damaged and needs to be removed for repair or replacement, the top cover 26 must be opened via the release latch 28 to access the fan modules 40 in the fan wall 14. This not only leads to inefficient operation as the electronic components in the chassis 12 are exposed as shown in FIG. 1C, but also causes backflow of air through the vacant space created after the defective fan module 42 is removed, as indicated by an arrow 50. The backflow results in a significant decrease in cooling efficiency and thus server operation while the fan module is being replaced.

Thus, there is a need for a releasable fan module structure that does not require a cover of a chassis to be removed to access the fan modules. There is a further need for a mechanism to prevent backflow when a fan module is removed. There is also a need for a fan module with mechanical components that allow for easy removal and locking in place.

### SUMMARY

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a computer system is disclosed. The computer system includes a chassis having a bottom panel and side walls. A top cover is joined to the side walls to cover the chassis. A releasable fan module is located on the bottom panel in proximity to one edge of the top cover. The releasable fan module includes a handle that may be positioned between a retracted position and an extended position to allow a user to remove the releasable fan module from the chassis. The assembly includes a latch mechanism on the edge of the top cover. The latch mechanism engages the handle to keep the handle in the retracted position.

A further implementation of the example computer system is where the computer system includes a pair of partitions attached to the bottom panel defining a slot for the releasable fan module. A rotatable windshield is attached between the partitions. The rotatable windshield has a down position under the fan module, and an up position blocking an area between the partitions when the releasable fan module is removed. Another implementation is where the rotatable windshield is mounted on the bottom panel via a mounting bracket. The mounting bracket is attached to one end of a torsion spring. Another end of the torsion spring is attached to the rotatable windshield. The torsion spring biases the rotatable windshield in the up position. Another implementation is where one of the partitions includes a spring plate having a clasp. The spring plate forces the clasp to contact the windshield and position the windshield at an angle between the up and down positions. Another implementation is where the latch mechanism includes a cage mounted under the top cover. The cage includes a spring coupled to the latch mechanism to engage the latch mechanism with the handle when the handle is in the retracted position. Another implementation is where the handle includes a slot, and the latch mechanism includes a tab that engages the slot. Another implementation is where the releasable fan module includes a first rail holding a first spring in contact with the handle. The handle is biased in the extended position by the first spring. Another implementation is where the releasable fan module includes second rail parallel to the first rail. The second rail holds a second spring in contact with the handle. The handle is biased in the extended position by the second spring. Another implementation is where the releasable fan module includes a fan housing having a proximal end coupled to the handle, and a distal end coupled to a fan rear frame that includes a second handle. Another implementation is where the handle includes a top plate having an edge with an indentation for gripping by an operator. Another implementation is where the fan module is one of a plurality of fan modules in proximity to the one edge of the top cover. The latch mechanism is one of a plurality of latch mechanisms on the one edge of the top cover.

According to certain aspects of the present disclosure, a releasable fan module is disclosed. The releasable fan module includes a fan housing that contains a fan motor and a fan. A front fan frame is attached to one end of the fan housing. A first rail extends from one side of the front fan frame. A second rail extends from a second side of the front fan frame. The second rail is parallel to the first rail. A handle is supported by the first rail and the second rail. The handle has a retracted position and an extended position.

A further implementation of the example fan module is where the handle includes a cover plate, a tab extending downward from the cover plate, and a slot in the tab. The slot engages a latch mechanism to hold the handle in the retracted position. Another implementation is where the first rail holds a first spring in contact with the handle. The handle is biased in the extended position by the first spring. Another implementation is where the second rail holds a second spring in contact with the handle. The handle is biased in the extended position by the second spring. Another implementation is where the releasable fan module further includes a fan back frame coupled to an opposite end of the fan housing. The fan back frame includes a second handle. Another implementation is where the handle includes a top plate and a pair of supports extending downward from the top plate. Another implementation is where the top plate includes opposite edges, each of the opposite edges including an indentation for gripping by an operator.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1A is a perspective view of a prior art computer server with a mechanism to remove a cover on the server chassis;

FIG. 1B is a perspective view of the prior art computer server with the cover removed showing the prior art fan modules;

FIG. 1C is a perspective view of the prior art computer server showing the problem of reverse air flow when a fan module is removed with the cover off;

FIG. 2A is an exploded perspective view of the example computer server and fan module, according to certain aspects of the present disclosure;

FIG. 2B is an exploded perspective view of the components of the fan module structure, according to certain aspects of the present disclosure;

FIG. 3A is a perspective view of the example releasable fan module, according to certain aspects of the present disclosure;

FIG. 3B is an exploded perspective view of the components of the example releasable fan module, according to certain aspects of the present disclosure;

FIG. 3C is a close-up perspective exploded view of the handle of the releasable fan module, according to certain aspects of the present disclosure;

FIG. 3D is a close-up perspective view of the assembly of the handle with the rear frame of the example fan module, according to certain aspects of the present disclosure;

FIG. 4A is a perspective view of the example top cover for the computer server that includes a set of latch cages, according to certain aspects of the present disclosure;

FIG. 4B is a close up perspective view of one of the latch cages shown in FIG. 4A, according to certain aspects of the present disclosure;

FIG. 5A is a front view of an example windshield used to block backflow when one of the fan modules in FIG. 2A is removed, according to certain aspects of the present disclosure;

FIG. 5B is a perspective view of the example windshield in FIG. 5B, according to certain aspects of the present disclosure;

FIG. 5C is a close-up perspective view of one of the brackets of the example windshield in FIG. 5C, according to certain aspects of the present disclosure;

FIG. 6A shows a front perspective view of the interior of the example server in FIG. 2A with example partitions for holding the fan modules, according to certain aspects of the present disclosure;

FIG. 6B shows a rear perspective view of the interior of the example server in FIG. 2A with example partitions for holding the fan modules, according to certain aspects of the present disclosure;

FIG. 6C is a close-up exploded view of one of the example partitions and a spring on one of the partitions, according to certain aspects of the present disclosure;

FIG. 6D is a close-up perspective view of one of the example partitions in the chassis, according to certain aspects of the present disclosure;

FIG. 7A is a perspective view of the example fan module with the handle in the retracted position, according to certain aspects of the present disclosure;

FIG. 7B is a side cutaway view of the example fan module with the handle in the retracted position, according to certain aspects of the present disclosure;

FIG. 7C is a perspective view of the handle of the example fan module being released to the extended position, according to certain aspects of the present disclosure;

FIG. 7D is a side cutaway view of the handle of the example fan module being released to the extended position, according to certain aspects of the present disclosure;

FIG. 8A is a perspective view shown in the example fan module being pulled out of the chassis, according to certain aspects of the present disclosure;

FIG. 8B is a cutaway perspective view of the windshield being deployed in the up position to block backflow once the fan module is removed, according to certain aspects of the present disclosure;

FIG. 8C is a cutaway front view showing the example windshield being deployed in the up position, according to certain aspects of the present disclosure;

FIG. 9A is a cutaway front view showing motion of the spring plate when an operator moves the windshield before the releasable fan module is installed in the chassis, according to certain aspects of the present disclosure; and

FIG. 9B is a cutaway front view showing the spring plate interacting with the windshield to hold the windshield at a fixed angle before the releasable fan module is installed in the chassis, according to certain aspects of the present disclosure.

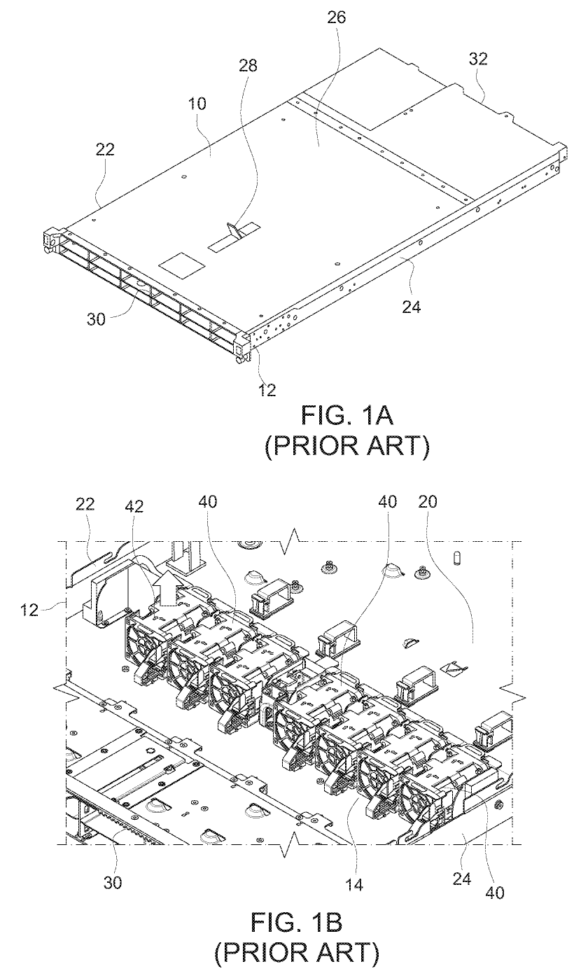

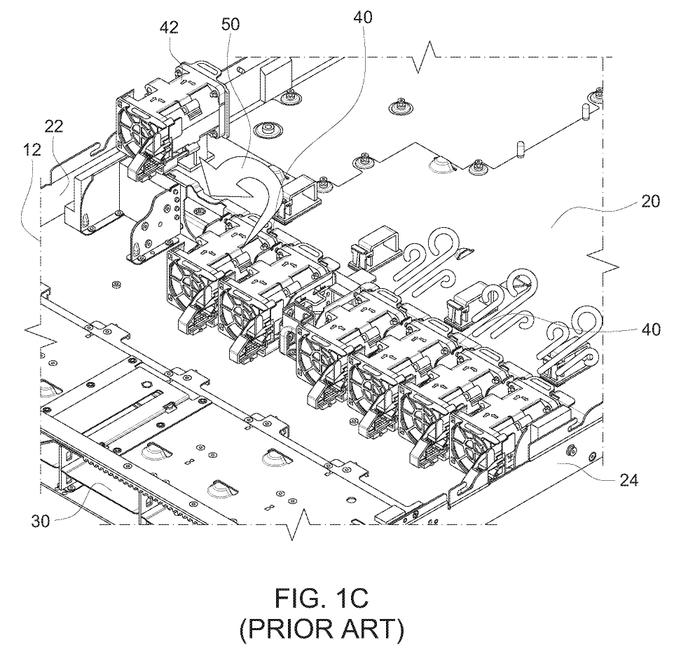

### DETAILED DESCRIPTION

The disclosure is directed to an improved design for releasable fan modules in a server chassis. The example design is directed toward providing more efficient removal and replacement of a fan module to enhance both the convenience and safety of the disassembly. The example design features a handle in each fan module, which allows the operator to remove the fan module without opening the top cover of the server to access the fan module. The operation of the handle is achieved through a releasing a latch located on an adjoining edge of a top cover. When the operator pushes the latch, the handle will extend up and allow the operator to pull out the fan module. The advantage of this design is that the operator can safely remove individual fan modules without opening the top cover, simply by using the handle mechanism.

In addition, the example releasable fan assembly also includes an example windshield. After the fan module is removed, the windshield automatically flips up to block the space created by the removed fan module. The windshield thus effectively prevents the occurrence of airflow backflow, thereby improving the overall heat dissipation performance of the fan modules while a fan module is replaced.

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

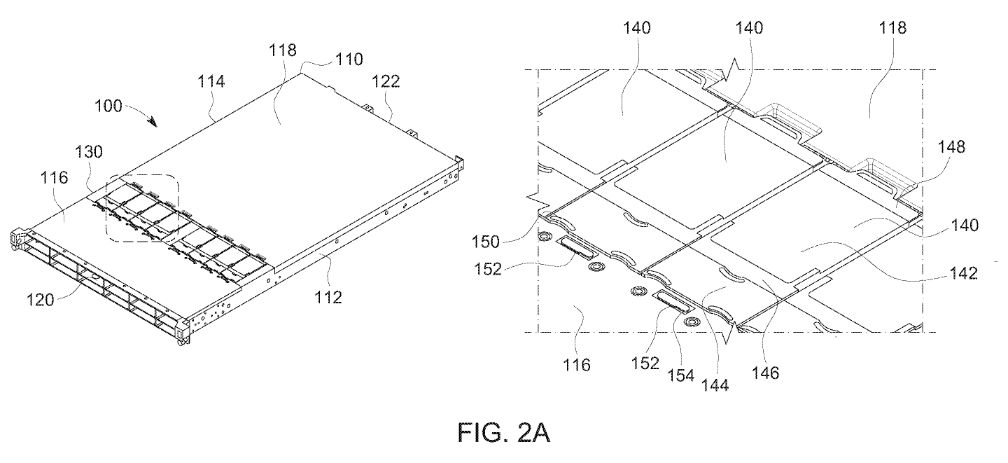

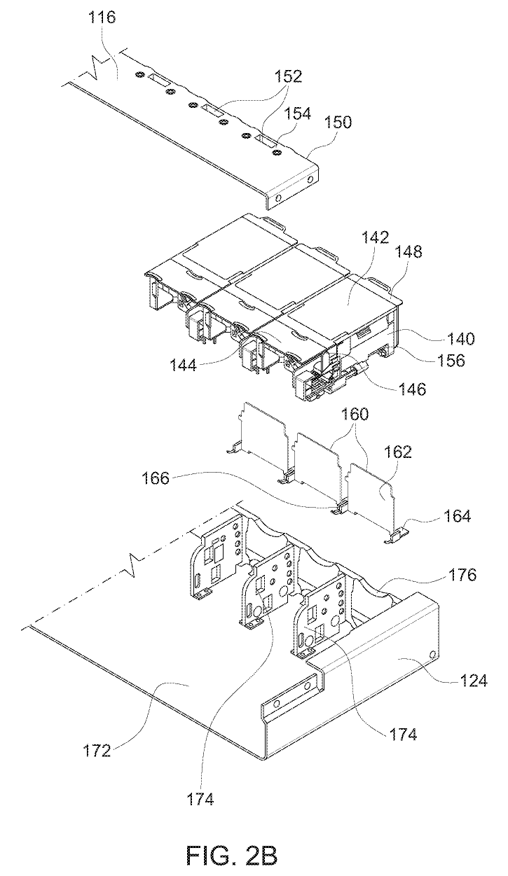

FIG. 2A is a perspective view of an example server 100 having a chassis 110 with an example fan assembly 130 that allows replacement of fan modules without removing a cover of the chassis 110. The chassis 110 holds electronic components (not shown) such as power supplies, circuit boards, processors, memory devices, and interface components on different circuit boards such as a mother board. The chassis 110 has an internal area for mounting the electronic components that is defined by the length of the chassis 110 and the width of the chassis 110. The electronic components generate heat, which may be radiated from attached heat sinks. While the chassis 110 is designed for a server, it is to be understood that the example fan assembly 130 may be used for cooling any suitable devices such as storage devices, routers, network switches, 5G components, and the like.

The chassis 110 includes a bottom panel and two side walls 112 and 114 that define the internal area of the chassis 110. A front top cover panel 116 and a rear top cover panel 118 define an area for the example fan assembly 130 between the front and rear top cover panels 116 and 118. The chassis 110 has a front end 120 and a rear end 122. The fan assembly 130 is positioned between the front end 120 and the rear end 122 in the interior of the chassis 110. The fan assembly 130 includes fan modules 140 that generate airflow to carry away generated heat in the interior of the chassis 110 from the electronic components in the chassis 110.

An inset in FIG. 2A shows the fan assembly 130 in greater detail. The fan assembly 130 includes a series of fan modules 140 that are arranged in a row. As may be seen in the inset, each of the fan modules 140 are positioned between the edges of the front top cover panel 116 and rear top cover panel 118. In this example, the fan assembly 130 includes eight fan modules 140, but any number of fan modules may be used. Each of the fan modules 140 includes a cover 142, a handle 144, a back frame 146, and a front frame 148. The handle 144 has a retracted position flush with the cover 142 and an extended position that pops the handle 144 up. A bordering edge 150 of the front top cover panel 116 includes a series of slots 154 with corresponding latch mechanisms such as latches 152 that each allow a user to release the handle 144 of the corresponding fan module 140 to the extended position. As will be explained, pushing the latch 152 in the slot 154 releases the handle 144 of the corresponding fan module 140. The handle 144 will pop up to an extended position to allow a user to pull out an individual fan module 140. This allows an individual fan module 140 to be removed without having to remove either top cover panel 116 or 118.

FIG. 2B shows an exploded view of the components for the example releasable fan assembly 130 to allow removal of the fan modules 140 without removing the top cover panels 116 or 118 in FIG. 2A. The fan assembly 130 includes the fan module 140 that can be removed from the chassis 110 without removing the top cover panels 116 and 118. The components that support the example fan assembly 130 include the front top cover panel 116, the set of fan modules 140, a set of windshield assemblies 160, and a fan support structure 170. Each of the fan modules 140 include a fan housing 156 that is attached between the back frame 146 and the front frame 148. The fan housing 156 includes the fan motor, control electronics, and the actual fan. The bordering edge 150 of the front top cover panel 116 includes the latches 152 that correspond to each of the fan modules 140. The windshield assemblies 160 include individual rotatable windshields 162 that correspond to each of the fan modules 140. The rotatable windshields 162 rotate about mounting brackets 164 and 166 to block space vacated by removal of the fan module 140 as will be explained below.

The fan support structure 170 is defined by different structures that are attached to a bottom panel 172 of the chassis 110. The fan support structure 170 includes a series of vertical partitions 174 that are attached to the bottom panel 172. The vertical partitions 174 define a set of slots that each hold one fan module 140. The vertical partitions 174 have a back edge that may be attached to a fan wall frame 176. As will be explained here, the fan wall frame 176 includes a lateral tab for mounting to the bottom panel 172 and individual apertures that align with the rear end of each of the corresponding fan modules 140.

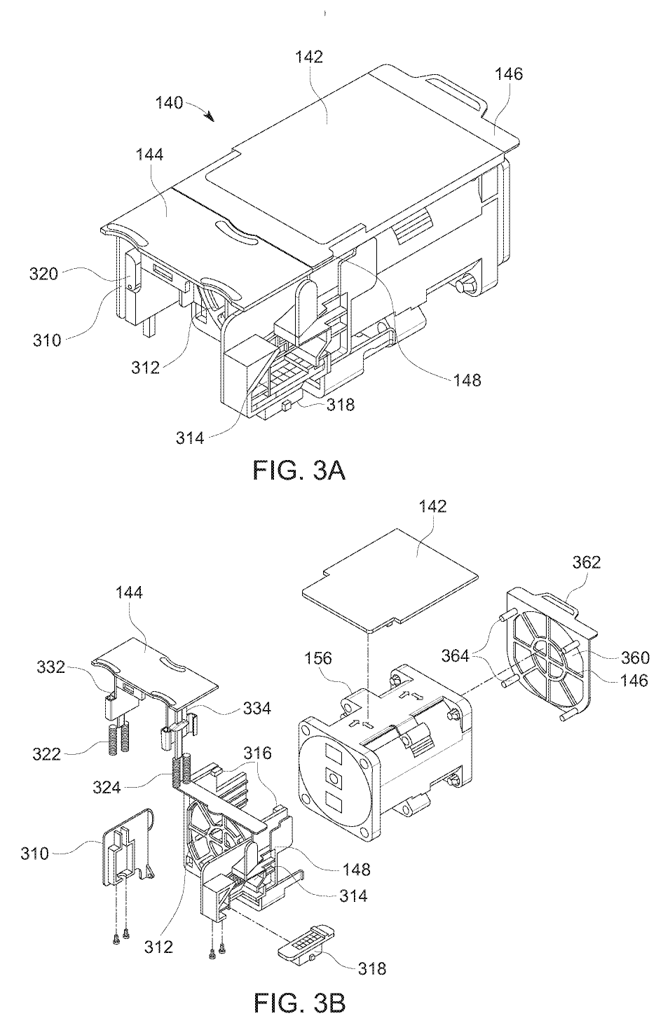

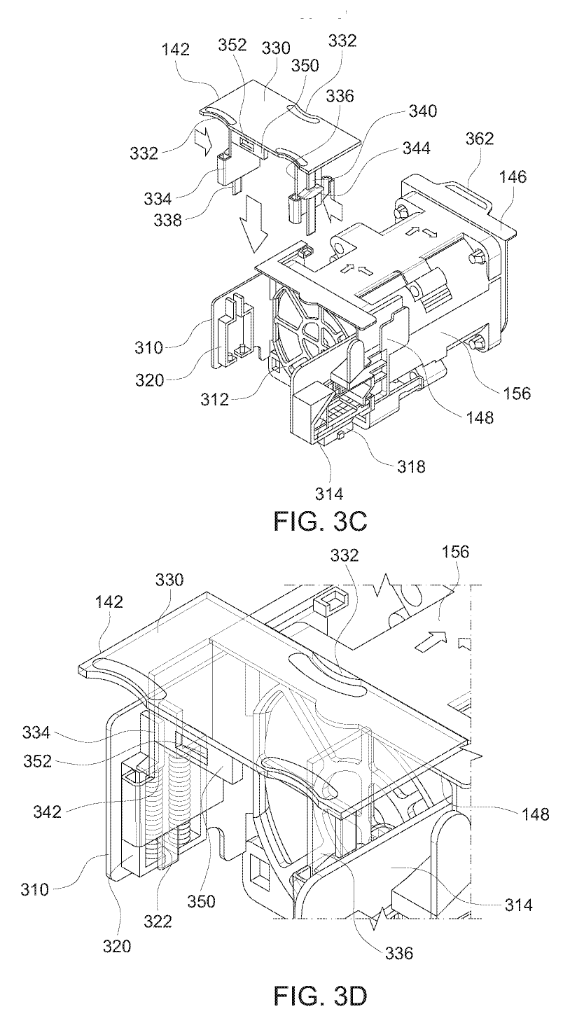

FIGS. 3A-3D show the components of one of the fan modules 140 in FIG. 2A. FIG. 3A shows a perspective view of the fan module 140. FIG. 3B shows an exploded view of the components of the fan module 140. FIG. 3C shows an isolated exploded perspective view of the handle 144 of the fan module 140. FIG. 3D shows an isolated perspective view of the handle 144 and assembled springs with the front frame 148 of the fan module 140.

As shown in FIGS. 3A-3D, a left rail 310 is attached to one side of a grill structure 312 of the front frame 148. The grill structure 312 includes a perpendicular panel 314 that extends on a side opposite the left rail 310. The grill structure 312 includes tabs 316 that may be inserted into corresponding slots in the fan housing 156 to hold the front frame 148 to the fan housing 156. A fan connector 318 may be attached to a retaining slot in the perpendicular panel 314. The bottom end of the fan connector 318 may be inserted into a fan connector socket on the bottom panel 172 to hold the fan module 140 in position.

The interior surface of the left rail 310 includes a spring box 320 that holds a pair of springs 322. Correspondingly, the interior surface of the perpendicular panel 314 includes a similar spring box that holds another pair of springs 324. The springs 322 and 324 may be attached to the respective spring boxes through spring pins. As will be explained, the handle 144 is locked in a retracted position in contact with the top edges of the left rail 310 and the perpendicular panel 314. The springs 322 and 324 are typically compressed in the spring boxes such as the spring box 320 when the handle 144 is locked in the retracted position.

As shown in more detail in FIGS. 3C-3D, the handle 144 includes a top cover plate 330. The opposite front and back of top cover plate 330 include indentations 332 at the respective edges that assist in a user gripping the top cover plate 330 when the handle 144 is in the extended position. The bottom surface of the top cover plate 330 is attached to parallel downwardly extending support arms 334 and 336. Each of the support arms 334 and 336 are attached to respective posts 338 and 340. In this manner, the handle 144 is largely free of air flow generated by the fan housing 156. Perpendicular tabs 342 and 344 are attached to the respective posts 338 and 340. The tabs 342 and 344 contact the springs 322 and 324 to compress the springs 322 and 324 when the handle 144 is in the retracted position. The front edge of the top cover plate 330 is attached to a perpendicular tab 350 that extends downward. A locking slot 352 is formed in the perpendicular tab 350. As will be explained, a tab attached to the latch 152 in FIG. 2B may be inserted in the locking slot 352 to hold the handle 144 in the down position.

The back frame 146 includes a grill 360 that allows air flow from the fan housing 156. The back frame 146 includes a handle 362 that may be gripped to assist in removing the fan module 140. The rear top cover panel 118 includes a set of indentations corresponding to each of the handles 362 of the respective fan modules 140. The back frame 146 includes a series of extended tabs 364 that may be inserted in corresponding slots in the fan housing 156 to hold the back frame 146 in place.

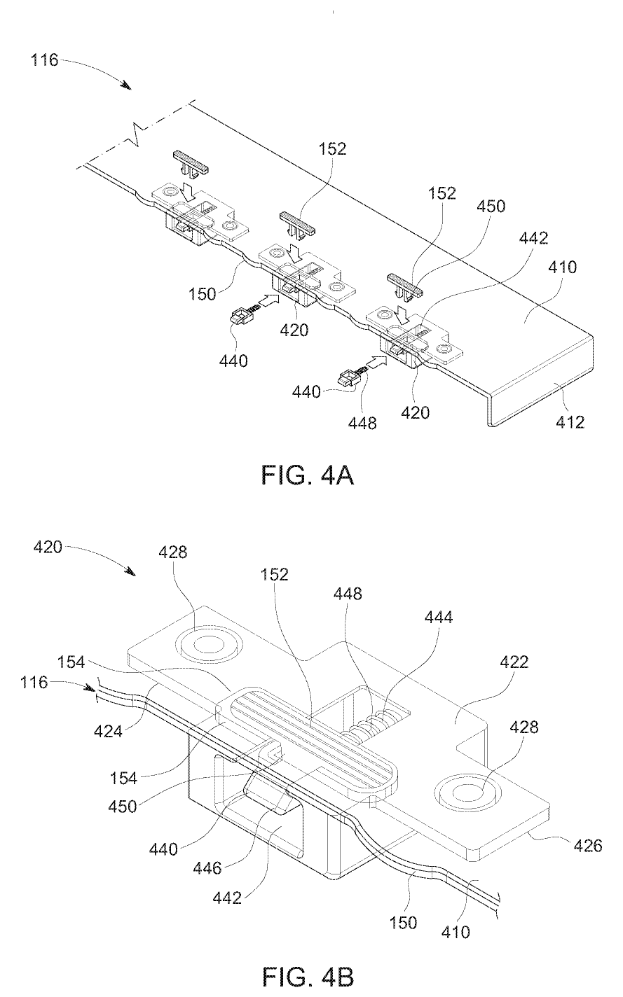

FIG. 4A shows a perspective see-through view of the front top cover panel 116 with the latch mechanisms that include the latches 152 and a set of switch sliders 440 in an exploded view. As explained herein, pushing the latches 152 away from the corresponding fan module 140 in FIG. 2 moves the corresponding switch slider 440 and releases the handle 144 of the fan module 140. The front top cover panel 116 includes a cover 410 that has side tabs 412 that allow the attachment of the front top cover panel 116 to the sides of the chassis 110 in FIG. 2A. The front top cover panel 116 supports a series of latch cages 420 that hold the respective latches 152 and define the slots 154 on the bordering edge 150. Each of the latch cages 420 are riveted to the underside of a lateral edge of the cover 410 in positions that align with the fan modules 140 in FIG. 2A.

FIG. 4B shows a close-up perspective view of one of the latch cages 420. The latch cage 420 includes a main body 422 that is attached to lateral tabs 424 and 426. The tabs 424 and 426 are attached via rivets 428 to the cover 410 to align the end of the latch cage 420 with the bordering edge 150. The main body 422 has a top plate planar with the tabs 424 and 426 that includes the slot 154. The main body 422 has a rectangular interior compartment 442 having a closed end and an open end. The interior compartment 442 holds the switch slider 440. The switch slider 440 includes a rod 444 and a tab 446 attached to one end of the rod 444. The tab 446 extends from the open end of the interior compartment 442. The tab 446 is sized to fit within the locking slot 352 in the handle 124 of the corresponding fan module shown in FIGS. 3C-3D. The other end of the rod 444 may contact the closed end of the interior compartment 442. A spring 448 is coiled around the rod 444 between the closed end of the interior compartment 442 and the latch 152. The spring force from the spring 448 forces the rod 444 away from the closed end of the interior compartment 442. The spring force of the spring 448 thus forces the tab 446 to extend out of the latch cage 420. The latch 152 is shaped to fit flush with the top surface of the cover 410 and may be moved laterally within the slot 154. The latch 152 includes a pair of clasps 450 that friction fit on the rod 444 to attach the rod 444 and the latch 152. The latch 152 thus may move the rod 444 and switch slider 440, and thus compress the spring 448 when the latch 152 is moved away from the bordering edge 150 of the cover 142.

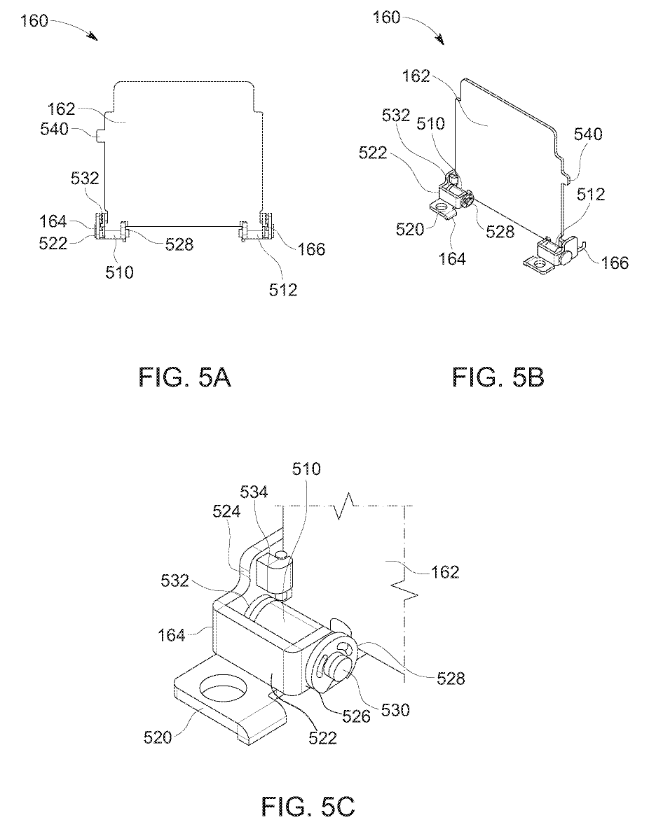

FIG. 5A is a front view of the windshield assembly 160 in FIG. 2B. FIG. 5B is a perspective view of the windshield assembly 160. The windshield 162 is shaped to block the aperture created when a fan module 140 is removed. The windshield 162 rotates about the mounting brackets 164 and 166. The windshield 162 includes two curved roller features 510 and 512 that may be mounted on the respective mounting brackets 164 and 166. As shown in the close-up view in FIG. 5C, the bracket 164 includes a mounting tab 520 that includes hole to allow the mounting tab 520 to be attached via a screw or other fastening device to the bottom panel of the server to fix the windshield 162 in position. The mounting tab 520 is attached to a cage 522 that includes parallel support panels 524 and 526. An E-shaped ring 528 is attached to a pin 530 that is supported by the panels 524 and 526. The E-shaped ring 528 prevents the pin 530 from being forced away from the support panel 526. The roller feature 510 is placed over the pin 530 to allow rotation relative to the mounting bracket 164. One end of a torsion spring 532 is joined to the roller feature 510. The other end of the torsion spring 532 is fixed to a hook 534 attached to the support panel 524. The coil of the torsion spring 532 is wrapped around the pin 530. An identical torsion spring 532, pin 530, and E-shaped ring 528 are provided for the other mounting bracket 166 and roller feature 512.

The rotation of the windshield 162 in the down position compresses the torsion springs 532 of each of the mounting brackets 164 and 166. The windshield 162 is held in the down position by the fan module 140, when the fan module 140 is installed as shown in FIG. 2A. When the fan module 140 is removed, the spring force from the torsion spring 532 causes the rotation of the roller feature 510 of the windshield 162 around the pin 530. This causes the windshield 162 to be rotated to the up position shown in FIG. 5B.

The windshield 162 utilizes the roller features 510 and 512 to serve as an axle for fixed rotation. To simplify the installation process, the mounting brackets 164 and 166 support rotation of the windshield 162 around the axis of the pins 530. This allows the windshield assembly 160 to be assembled outside the chassis and once assembled, the entire windshield assembly 160 may be inserted on the bottom panel 172 near a corresponding fan module 140. The torsion springs 532 provide the spring force for the rotation of the windshield 162 in the up position to block backflow. Finally, the E-shaped ring 528 is used to secure the windshield 162, torsion spring 532, mounting bracket 164, and pin 530. The E-shaped ring 528 is installed on the inner sides of the mounting brackets 164 and 166 of the windshield assembly 160. The windshield 162 also includes an extended tab 540 on one side that allows the windshield 162 to be locked at a fixed angle from a spring plate on a partition as will be explained below.

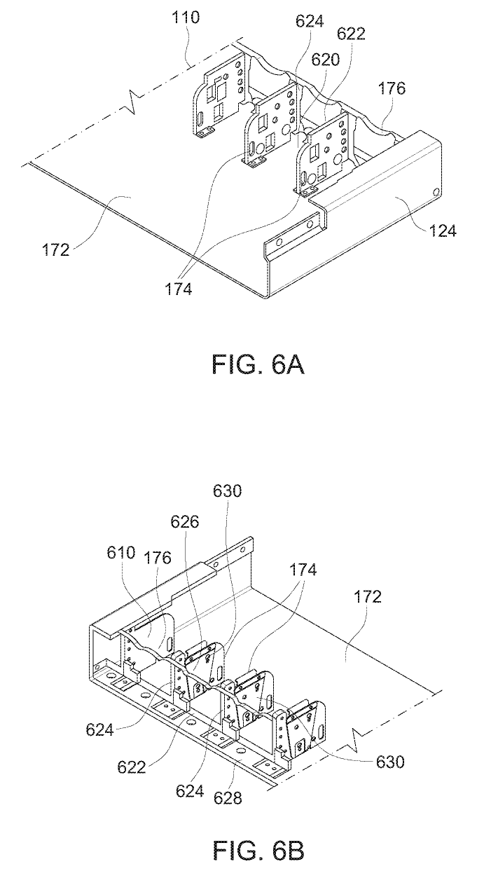

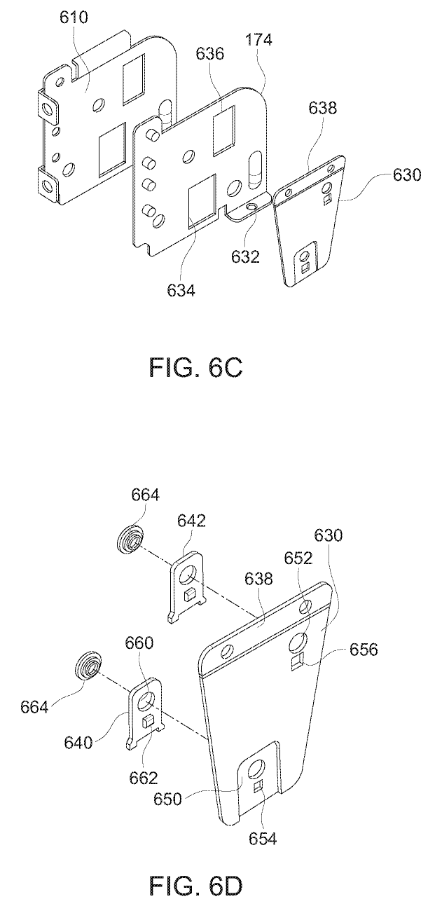

FIG. 6A is a front perspective view of the example partition 174 that allow the positioning of the example fan modules in the chassis 110 in FIG. 2A. FIG. 6B is a back perspective view of the interior of the chassis. FIG. 6C is an isolated exploded view of the components of the partitions in FIGS. 6A-6B. FIG. 6D is an exploded view of one of the partitions 174 in FIGS. 6A-6B. The chassis 110 includes the bottom panel 172 that has a series of registration features such as rivet holes and screw holes that allow the attachment of the fan wall frame 176, an end partition 610, and the middle partitions 174. The partitions 610 and 174 are attached perpendicularly to the fan wall frame 176 and are attached parallel to each other on the bottom panel 172. Thus, fan slots such as a fan slot 620 are created by a portion of the fan wall frame 176, and two partitions 174. The slot 620 is sized to accommodate the width of one of the fan modules 140. The portion of the fan wall frame 176 in alignment with each fan module 140 includes a circular aperture 622 that allows airflow to be generated from the fan module 140. Lateral struts 624 extend between the apertures 622. A top bar 626 and a bottom tab 628 are connected to the opposite end of all the lateral struts 624. The bottom tab 628 includes registration features such as screw or rivet holes to allow the fan wall frame 176 to be attached to the bottom panel 172. Each of the partitions 174 has a trapezoidal spring plate 630 attached to allow contact with the windshield 162.

As shown in FIG. 6C, the partition 174 includes a perpendicular tab 632 that includes holes for insertion of rivets or screws for attachment to the bottom panel 172. The partition 174 includes a lower aperture 634 and an upper aperture 636 that are aligned with a lower clasp 640 and an upper clasp 642 respectively that are attached to the spring plate 630. A top edge 638 of the spring plate 630 includes mounting holes for attaching the top edge 638 of the spring plate 630 to the top edge of the of the partition 174, as shown in FIG. 6B. Thus, the bottom end of the spring 630 and attached clasps 640 and 642 may be flexed away from the partition 174. When the spring plate 630 is attached to the partition 174, the clasps 640 and 642 are positioned between the spring plate 630 and the partition 174. The clasps 640 and 642 extend outward from the respective apertures 634 and 636.

The spring plate 630 as shown in FIG. 6D includes two mounting holes 650 and 652 and corresponding lower and upper guide holes 654 and 656. The clasps 640 and 642 each have a hole 660 and a square guide pin 662. The clasps 640 and 642 are thus attached to the spring plate 630 via inserting the square guide pin 662 in the respective guide holes 654 and 656. A rivet 666 is inserted through the hole 660 to hold the respective clasps 640 and 642 in the mounting holes 650 and 652. When the spring plate 630 is relaxed, the clasps 640 and 642 are positioned in the respective apertures 634 and 636 of the partition 174.

The partitions 174 and the fan wall frame 176 on the bottom panel 172 are used to divide the fan assembly 130 into sections, allowing for aligned assembly of each of the fan modules 140. Guide holes and nuts are created on the bottom panel 172 for each section to facilitate the positioning and assembly of the windshield 162. Additionally, the metal spring plates 630 are riveted to the partitions 174 simultaneously. The two clasps 640 and 642 are fixed at the surface of the spring plate 630. The purpose of this design is to address the difficulty in simultaneously pressing down the windshield 162 and installing the fan module 140. With the spring plate 630 and the clasps 640 and 642, the operator can first press down the windshield 162 so that the lower plastic clasp 640 on the metal spring 630 contacts the windshield 162 and holds the windshield 162 at a fixed angle. At this point, the operator can use both hands to install the fan module 140 into the server chassis.

The assembly method for the fan assembly 130 may be as follows. An operator first assembles the partitions 174 and the fan wall frame 176 to the bottom panel 172 in FIG. 6C. The rivet holes in the bottom tab 628 of the fan wall frame 176 are aligned with the corresponding holes in the bottom panel 172. Rivets are then used to attach the fan wall frame 176 to the bottom panel 172.

The plastic clasps 640 and 642 are attached to the metal spring plates 630 for each of the partitions 174. The square guide pins 662 of the plastic clasps 640 and 642 are inserted into the square guide holes 654 and 656 on the metal spring plate 630 as shown in FIGS. 6C-6D. The two plastic clasps 640 and 642 are secured onto the metal spring plate 630 using a mini hinge 664. The partitions 174 and 610 are then individually assembled. The partitions 174 and 610 are positioned by aligning holes near the top of the partitions 174 to corresponding holes in the top edge 638 of the spring plates 630. Rivets are then used to attach each of the partitions 174 to the corresponding metal spring plates 630. Thus, the metal spring plates 630 are positioned on one side of the partitions 174 and fixed in place using rivets at the top edge 638.

The fan partitions 174 are then attached to the fan wall frame 176. In this example, the rear section of each of the partitions 174 may be inserted in a hole of the back of the fan wall frame 176. The partition 174 may then be rotated 90 degrees to align the rivet holes on the tab 632 of the partition 174 to corresponding holes in the bottom panel 172. The partitions 174 are then fastened to the bottom panel 172 using rivets.

The components of the windshield assemblies 160 are then assembled. The torsion springs 532 and the mounting brackets 164 and 166 are aligned with the respective rolling features 510 and 512 of the windshield 162. Once aligned, the respective pins 530 are inserted through the mounting brackets 164 and 166, the torsion springs 532, and the roller features 510 and 512 of the windshield 162. The E-shaped rings 528 are then inserted onto a pin groove on the pins 530 to ensure that the mounting brackets 164 and 166 are fully assembled to the windshield 162. Finally, the windshield 162 and mounting brackets 164 and 166 are positioned between the partitions 174.

The holes in the mounting brackets 164 and 166 are aligned with the guide holes on the bottom panel 172. Once positioned, one end of the torsion springs 532 is installed into a flat feature of the partition 174. An end of the torsion spring 532 is pushed outward and then may be pressed downward so that the end of the torsion spring 532 is secured into the partition 174. Finally, two screws at the rear side of the mounting brackets 164 and 166 are installed to fix the windshield 162 to the bottom panel 172.

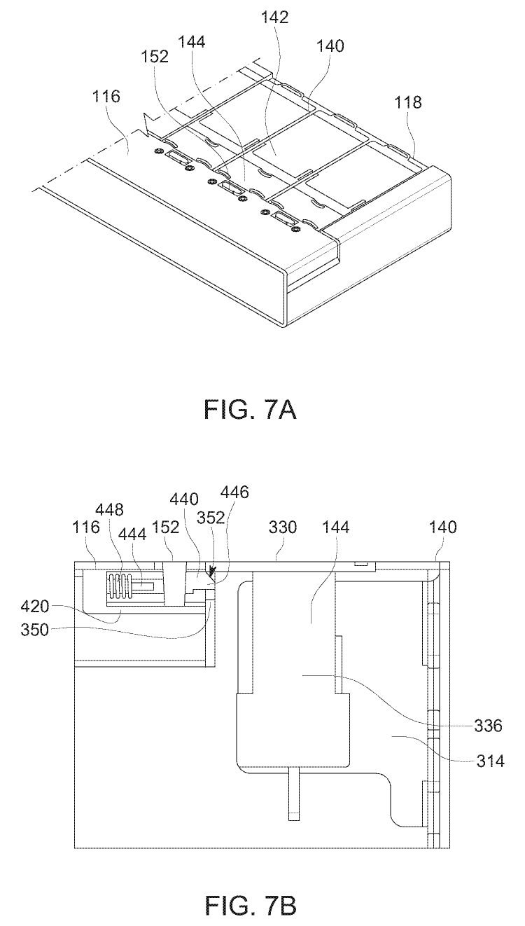

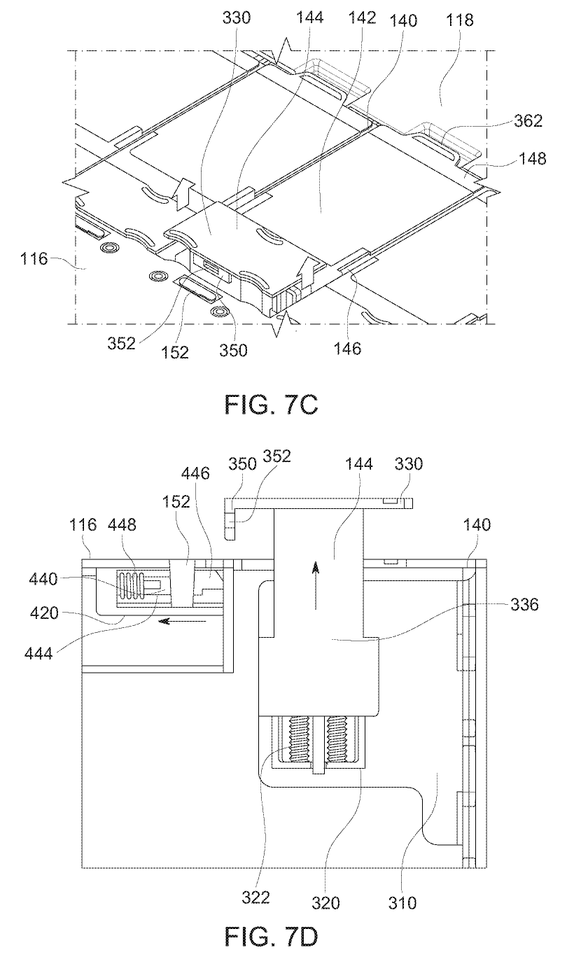

FIGS. 7A-7C show the process of removing one of the fan modules 140 without removing a cover of the server and deploying the windshield 162 to stop backflow. FIG. 7A is a perspective view of the example fan module 140 with the handle 144 in the locked down position. FIG. 7B is a side cutaway view of the example fan module 140 with the handle 144 in the locked down position. The handle 144 is locked in place by the spring 448 in the latch cage 420 forcing the tab 446 into the locking slot 352 of the perpendicular tab 350 of the handle 144. The tabs 342 and 344 supported by posts 338 and 340 on respective support arms 334 and 336 of the handle 144 (shown in detail in FIG. 3B and 3D) thus compress the springs 322 and 324. The fan connector 318 is inserted in the corresponding fan connector socket in the bottom panel 172. The latch 152 locks the handle in place. The fan module 140 is thus fixed between the partitions 174 and forces the windshield 162 in the down position.

When the fan module 140 needs to be removed, an operator slides the latch 152 away from the fan module 140 to release the handle 144. FIG. 7C is a perspective view of the handle 144 of the example fan module 140 in the extended position after being released. FIG. 7D is a side cutaway view of the handle 144 of the example fan module 140 in the extended position after being released.

FIG. 7D shows that the latch 152 on the latch cage 420 serves as the handle switch for the fan module 140. The latch 152 controls the positioning of the handle 144 of the corresponding fan module 140. The latch 152 is assembled with the switch slider 440 through the clasps 450 as shown in FIG. 4B. When the latch 152 is pushed away from the fan module 140 in the slot 154, it releases the tab 446 of the switch slider 440 from the locking slot 352 of the handle 144. This releases the handle 144, and the spring force from the springs 322 and 324 pop the handle 144 to the extended position. The spring 448 installed behind the switch slider 440 causes the switch slider 440 to automatically return to its original extended position once pressure on the latch 152 is removed. This ensures that when the handle 144 is pressed back to the closed state, the handle 144 can be securely fixed in the down position.

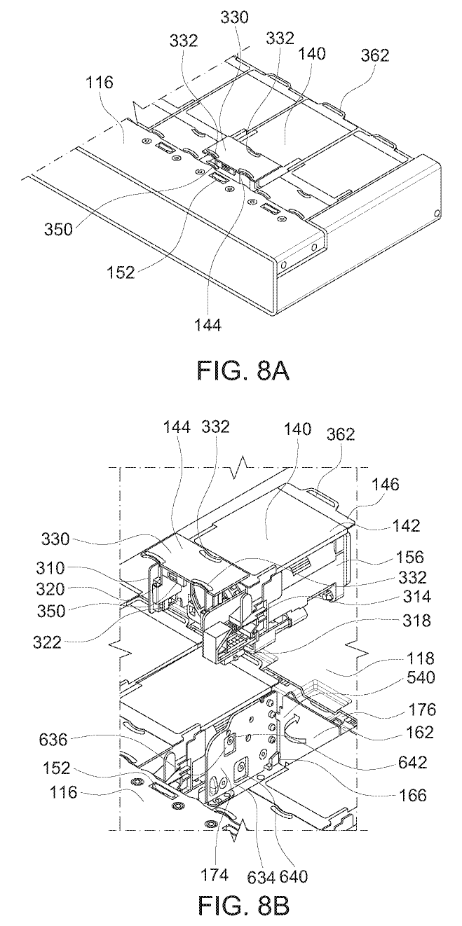

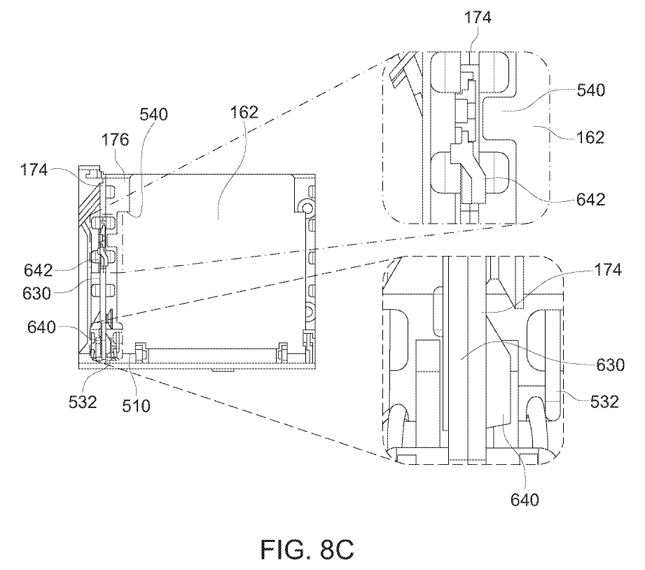

FIG. 8A is a perspective view showing the example fan module 140 being pulled out of the chassis 110. FIG. 8B is a cutaway perspective view of the windshield 162 being deployed to block backflow once the fan module 140 is removed. FIG. 8C is a front cutaway view of the windshield 162 being deployed. The springs 322 and 324 installed at the left rail 310 and the perpendicular panel 314 provide upward force to the support arms 334 and 336 of the handle 144 when the latch 152 is pushed. The left rail 310 and the panel 314 of the front frame 148 limit the lateral movement of the handle 144. The cover 142 positioned over the fan housing 156 ensures that airflow does not backflow from above the fan module 140. In this example, the operator grips the fan module 140 by the now extended handle 144 and the handle 362 on the fan back frame 146 to pull the fan module 140 out of the chassis 110.

During the removal of the fan module 140, the perpendicular panel 314 of the fan back frame 146 will continue to push the upper plastic clasp 642 on the metal spring plate 630. This action pushes the metal spring plate 630 toward the partition 174, keeping the lower plastic clasp 640 disengaged from the extended tab 540 on the windshield 162. At this point, the windshield 162 will be flipped by the spring force from the torsion springs 532 on the mounting brackets 164 and 166 of the windshield assembly 160 as shown in FIGS. 8B-8C.

After the fan module 140 is completely removed from the chassis 110, the lower plastic clasp 640 on the metal spring plate 630 will return to a position extending from the partition 174 as shown in the inset in FIG. 8C, as the frame of the fan module 140 is no longer in contact with the clasp 640. The windshield 162 will flip up from the force of the torsion springs 532 and block the aperture 622 of the fan wall frame 176, preventing airflow from reversing as shown in FIG. 8B and 8C.

When reinstalling the example fan module 140 into the chassis 110, the windshield 162 is raised in a blocking position as shown in FIG. 8B and FIG. 8C. The windshield 162 must be rotated back to the bottom panel 172 of the chassis 110, once the fan module 140 is inserted to allow the fan module 140 to carry out cooling. Before the fan module 140 is inserted, an operator may press the windshield 162 downward until the windshield 162 rotates over the fixed surface of the lower plastic clasp 640 on the metal spring plate 630.

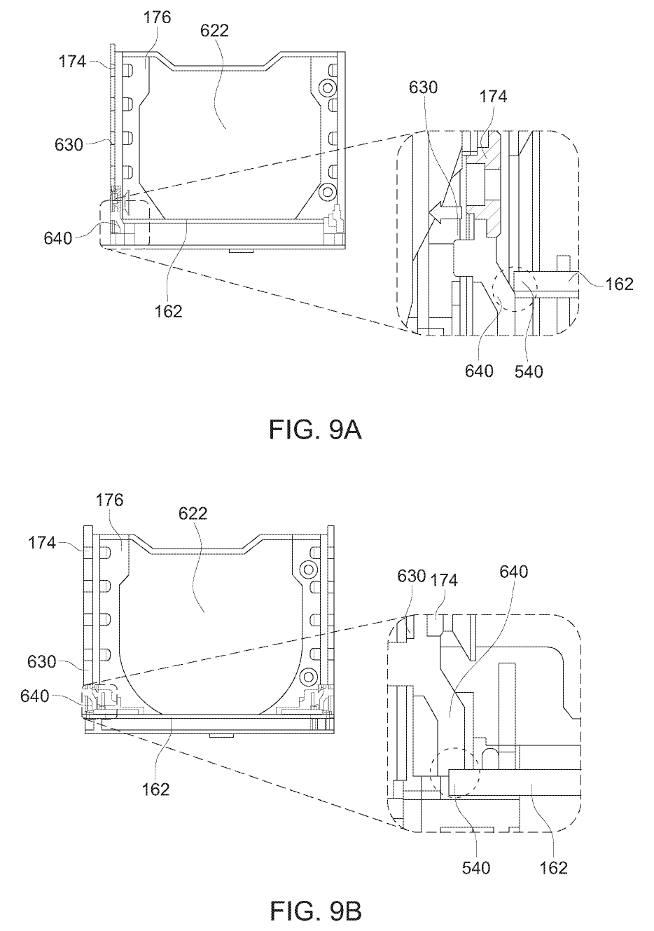

FIG. 9A is a front cutaway view of the rotation of the windshield 162 by the operator. During this motion, the extended tab 540 of the windshield 162 will contact the plastic clasp 640, pushing the metal spring plate 630 away from the partition 174 as shown in detail in the inset in FIG. 9A. At this point, the operator continues to push the windshield 162 downward, passing through the fixed surface of the plastic clasp 640 as shown in FIG. 9B. After the metal spring plate 630 rebounds and the downward pressure is stopped, the windshield 162 will be fixed at that angle by the plastic clasp 640 on the metal spring plate 630 contacting the extended tab 540 of the windshield 162.

Next, the fan module 140 is installed into the system. By pressing down on the fan module 140 between the partition 174 and the spring plate 630 of the opposite partition 174, the windshield 162 is pushed all the way down to the bottom panel 172 of the chassis 110 under the fan module 140. The fan connector 318 shown in FIG. 3C will be mated to a corresponding socket on the bottom panel 172. The operator then presses down on the handle 144. Once the handle 144 is pressed down, the locking slot 352 of the perpendicular tab 350 is aligned with the tab 446 of the switch slider 440 as shown in FIG. 7B. The spring force from the spring 448 pushes the switch slider 440, and thus the tab 446, into the locking slot 352 to complete the fan assembly and lock the handle 144 and fan module 140 in place, as shown in FIGS. 7A-7B.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A computer system, comprising:
a chassis having a bottom panel and side walls;
a top cover joined to the side walls to cover the chassis;
a releasable fan module being located on the bottom panel in proximity to an edge of the top cover, the releasable fan module including a fan, a fan housing holding the fan, and a handle attached to the fan housing, the handle moveable relative to the fan housing between a retracted position and an extended position to allow a user to pull the handle and remove the attached releasable fan module from the chassis; and a latch mechanism positioned on the edge of the top cover, the latch mechanism engaging the handle to keep the handle in the retracted position

2. The computer system of claim 1, further comprising:a pair of partitions attached to the bottom panel, the pair of partitions defining a slot for the releasable fan module; anda rotatable windshield attached between the pair of partitions, the rotatable windshield having a down position under the fan module, and an up position blocking an area between the partitions when the releasable fan module is removed.

3. The computer system of claim 2, wherein the rotatable windshield is mounted on the bottom panel via a mounting bracket, the mounting bracket being attached to one end of a torsion spring, and another end of the torsion spring being attached to the rotatable windshield, the torsion spring biasing the rotatable windshield in the up position.

4. The computer system of claim 2, wherein one of the partitions includes a spring plate having a clasp, the spring plate forcing the clasp to contact and position the windshield at an angle between the up and down positions.

5. The computer system of claim 1, wherein the latch mechanism includes a cage mounted under the top cover, the cage including a spring coupled to the latch mechanism to engage the latch mechanism with the handle when the handle is in the retracted position.

6. The computer system of claim 5, wherein the handle includes a slot, and the latch mechanism includes a tab that engages the slot.

7. The computer system of claim 1, wherein the releasable fan module includes a front frame attached to the fan housing, and wherein the handle includes a top cover plate and a support arm assembly extending downward from the top cover plate, wherein the front frame includes a first rail with a spring box holding a first spring in contact with the support arm assembly of the handle, wherein the arm assembly is partially inserted in the spring box, and the handle being biased in the extended position by the first spring.

8. The computer system of claim 7, wherein the releasable fan module includes second rail parallel to the first rail, the second rail holding a second spring in contact with the handle, the handle being biased in the extended position by the second spring.

9. The computer system of claim 1, wherein the fan housing hasa proximal end coupled to a fan front frame supporting the handle, and a distal end coupled to a fan rear frame that includes a rearhandle.

10. The computer system of claim 1, wherein the handle includes a top plate having an edge with an indentation for gripping by an operator.

11. The computer system of claim 1, wherein the releasable fan module is one of a plurality of fan modules in proximity to the edge of the top cover, and the latch mechanism is one of a plurality of latch mechanisms on the edge of the top cover.

12. A releasable fan module comprising:a fan housing containing a fan motor and a fan;a front fan frame attached to one end of the fan housing;a first rail extending from one side of the front fan frame;a second rail extending from a second side of the front fan frame, the second rail parallel to the first rail; anda handle attached to the first rail and the second rail, the handle moving between a retracted position and an extended position to allow a user to pull the handle and remove the fan housing.

13. The releasable fan module of claim 12, wherein the handle includes atop cover plate, a tab extending downward from the top cover plate, and a slot in the tab, the slot engaging a latch mechanism to hold the handle in the retracted position.

14. The releasable fan module of claim 12, wherein the handle includes a top cover plate and a support arm assembly extending down ward from the top cover plate, wherein the first rail includes a spring box holding a first spring in contact with the support arm assembly of the handle, wherein the arm assembly is partially inserted in the spring box, and the handle being biased in the extended position by the first spring.

15. The releasable fan module of claim 14, wherein the second rail holds a second spring in contact with the handle, the handle being biased in the extended position by the second spring.

16. The releasable fan module of claim 12, further comprising a back fan frame coupled to an opposite end of the fan housing, the back fan frame including a second handle.

17. The releasable fan module of claim 14, wherein the support arm assembly includes a post attached to a tab contacting the first spring in the spring box .

18. The releasable fan module of claim 17, wherein the top plate includes opposite edges, each of the opposite edges including an indentation for gripping by an operator.

19. The computer system of claim 1, further comprising a fan assembly area positioned between a front end and rear end of chassis on the bottom panel, wherein the top cover has an opposite edge forming a front end of the chassis and the edge of the top cover defines one end of the fan assembly area, wherein the fan module is removable from the fan assembly area in a vertical direction relative to the bottom panel.

20. The computer system of claim 19, further comprising a rear top cover plate attached between the side walls, wherein the fan assembly area is defined by a space between the rear top cover plate and the front top cover plate.
